(19) United States
(12) Patent Application Publication
(10) Pub. No.: US 2010/0051998 A1
(43) Pub. Date: Mar. 4, 2010

(54) Organic light emitting diode and method of fabricating the same

(75) Inventor: Jwo-Huei Jou, Hsinchu (TW)

Correspondence Address: ROGER H. CHU, 19499 ERIC DRIVE, SARATOGA, CA, 95070, US

(73) Assignee: National Tsing Hua University (Taiwan), Hsinchu (TW)

(21) Appl. No.: 12/552,286

(22) Filed: Sep. 2, 2009

(30) Foreign Application Priority Data
Sep. 3, 2008 (TW) 097133672

(51) Int. Cl. H01L 51/52; H01L 51/56

(52) U.S. Cl. 257/98; 438/29; 257/40; 257/E51.018; 257/E21.158

(57) ABSTRACT

The present invention discloses an organic light emitting diode and a method of fabricating the organic light emitting diode. The OLED device includes one or more light emitting layers, and the light emitting layer is composed of one or more light emitting materials and one or more subject materials, and the subject material has a molecular polarity different from the molecular polarity of the light emitting material, such that the light emitting molecules can be self dispersed to emit a more reddish light color or a light color of a longer wavelength.

### CROSS-REFERENCE TO RELATED APPLICATION

This application claims foreign priority from a Taiwan Patent Application, Ser. No. 097133672, filed on Sep. 3, 2009.

### BACKGROUND OF THE INVENTION

1. Field of the Invention

The present invention relates to an organic light emitting diode and a method of fabricating the organic light emitting diode, in particular to a diode with a light emitting layer composed of one or more subject materials and one or more object materials, and the polarity of the subject material is very close to the polarity of the light emitting material, such that light emitting molecules cannot be self-dispersed to emit a more reddish blue light color or a light color of a longer wavelength.

2. Description of the Related Art

Organic electro-luminescence display (Organic EL Display) is also known as organic light emitting diode (OLED) developed by C. W. Tang and S. A. VanSlyk, et al. of Kodak in 1987, and first introduced to be made by vacuum evaporations, wherein a hole transporting material and an electron transporting material are coated onto a transparent indium tin oxide (ITO) glass sheet, and then a metal electrode is evaporated to form an OLED device having a self luminance. Organic EL display has become a new-generation display due to its high brightness, quick screen response, thin, light, short and compact design, true color, free of viewing angle difference. In addition, the organic EL display does not require any LCD backlight panel, so as save light sources and power consumption.

With reference to FIG. 1 for a cross-sectional view of a first conventional OLED device, the OLED device includes a transparent substrate 11, a transparent anode 12 (indium tin oxide, ITO), a hole transporting layer 13 (HTL), an organic light emitting layer 14 (EL), an electron transporting layer 15 (ETL), an electron injection layer 16 (EIL) and a metal cathode 17 installed sequentially from top to bottom. If a forward bias voltage is applied, a hole 131 will be injected from an anode 12, and an electron 151 will be injected from a cathode 17. Due to a potential difference caused by an external electric field, the electron 151 and the hole 131 are moved in a thin film, so that a recombination occurs in the organic light emitting layer 14. Energy released by combining a portion of electron holes activates light emitting molecules of the organic light emitting layer 14 into an excited state. If the light emitting molecules are degenerated from the excited state to a ground state, a specific percentage of energy is released in form of photons, and the light emitted is an organic light emission.

With reference to FIG. 2 for a cross-sectional view of a second conventional OLED device, the OLED device was developed by C. W. Tang of Kodak in 1982 and disclosed in U.S. Pat. No. 4,356,429, and the OLED device of this preferred embodiment comprises a transparent substrate 21, a transparent anode 22, a hole injection layer 23, a light emitting layer 24 and a metal cathode 25 installed sequentially from top to bottom. If a forward bias voltage is applied, a hole will be injected from an anode 22, and an electron will be injected from a cathode 25. Due to a potential difference caused by an external electric field, the electron and the hole are moved in a thin film, so that a recombination occurs in the light emitting layer 24. Energy released by combining a portion of electron holes activates light emitting molecules of the light emitting layer 24 into an excited state. If the light emitting molecules are degenerated from the excited state to a ground state, a specific percentage of energy is released in form of photons, and the light emitted is an organic light emission.

With reference to FIG. 3 for a cross-sectional view of a third conventional OLED device, the OLED device was developed by C. W. Tang of Kodak in 1988 and disclosed in U.S. Pat. No. 4,720,432, and the OLED device of this preferred embodiment comprises a transparent substrate 31, a transparent anode 32, a hole injection layer 33, a light emitting layer 34 with an electron transporting function and a metal cathode 35.

If a forward bias voltage is applied, a hole will be injected from an anode 32, and an electron will be injected from a cathode 35. Due to a potential difference caused by an external electric field, the electron and the hole are moved in a thin film, so that a recombination occurs in the light emitting layer 34. Energy released by combining a portion of electron holes activates light emitting molecules of the light emitting layer 34 into an excited state. If the light emitting molecules are degenerated from the excited state to a ground state, a specific percentage of energy is released in form of photons, and the light emitted is an organic light emission.

With reference to FIG. 4 for a cross-sectional view of a fourth conventional OLED device, the OLED device was developed by Saito et al in 1992 and disclosed in U.S. Pat. No. 5,085,946, and the OLED device of this preferred embodiment comprises a transparent substrate 41, a transparent anode 42, a hole transporting layer 43, a light emitting layer 44 with an electron transporting function, and a metal cathode 45 installed sequentially from top to bottom, for producing an organic light emission.

With reference to FIG. 5 for a cross-sectional view of a fifth conventional OLED device, the OLED device was developed by Saito et al and disclosed in U.S. Pat. No. 5,085,947, and the OLED device of this preferred embodiment comprises a transparent substrate 51, a transparent anode 52, a light emitting layer 53 with a hole transporting function, an electron transporting layer 54 and a metal cathode 55 installed sequentially from top to bottom, for producing an organic light emission.

With reference to FIG. 6 for a cross-sectional view of a sixth conventional OLED device, the OLED device was developed by C. W. Tang, et al. and disclosed in the Journal of Applied Physics, Vol. 65, Page 3610 (1989), and the OLED device is a doped OLED device comprising a transparent substrate 61, a transparent anode 62, a hole transporting layer 63, a single-composition light emitting layer 64, a dye-doped light emitting layer 65, a single-composition light emitting layer 66 and a metal cathode 67 installed sequentially from top to bottom, for producing an organic light emission.

With reference to FIG. 7 for a cross-sectional view of a seventh conventional OLED device, the OLED device was developed by C. H. Chen, et al. and disclosed in the Applied Physics Letters, Vol. 85, Page 3301 (2004), and the OLED device is a doped OLED device comprising a transparent substrate 71, a transparent anode 72, a hole injection layer 73, a hole transporting layer 74, a dye-doped light emitting layer 75, an electron transporting layer 76, an electron injection layer 77 and a metal cathode 78 installed sequentially from top to bottom, for producing an organic light emission.

In view of the drawbacks of the prior art, the inventor of the present invention based on years of experience in the related industry to conduct extensive researches and experiments, and finally developed an organic light emitting diode and provided a method of fabricating the organic light emitting diode, so that the electroluminescence of the light emitting molecules will not have a red shifting easily, so as to emit a more reddish light color or a light color with a longer wavelength as a basis for achieving the foregoing objectives.

### SUMMARY OF THE INVENTION

Therefore, it is a primary objective of the present invention to overcome the foregoing shortcomings by providing an organic light emitting diode and a method of fabricating the organic light emitting diode, wherein the light emitting layer in the diode includes one or more subject materials and one or more object materials, and the polarity of the subject material is different from the polarity of the light emitting material, such that light emitting molecules cannot be dispersed easily, and a darker red or a light color with a longer wavelength will be emitted.

To achieve the foregoing objective, the present invention provides an organic light emitting diode (OLED) device comprising a substrate, a first electrically conductive layer, a light emitting layer, an electron transporting layer, an electron injection layer and a second electrically conductive layer, wherein the light emitting layer is composed of one or more subject materials and one or more object materials, and the polarity of the subject material has a bigger difference from the polarity of the light emitting material to prevent the light emitting molecules in the light emitting layer from being dispersed, such that the device emits a more red shifting light color.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 is a cross-sectional view of a first conventional OLED device;

FIG. 2 is a cross-sectional view of a second conventional OLED device;

FIG. 3 is a cross-sectional view of a third conventional OLED device;

FIG. 4 is a cross-sectional view of a fourth conventional OLED device;

FIG. 5 is a cross-sectional view of a fifth conventional OLED device;

FIG. 6 is a cross-sectional view of a sixth conventional OLED device;

FIG. 7 is a cross-sectional view of a seventh conventional OLED device;

FIG. 8 is a cross-sectional view of an OLED device in accordance with a preferred embodiment of the present invention;

FIG. 9 is a flow chart of a method of fabricating an OLED device in accordance with a preferred embodiment of the present invention;

FIG. 10 shows the difference between the present invention and the prior art, and particularly using an OLED electroluminescence spectroscopy for the comparison.

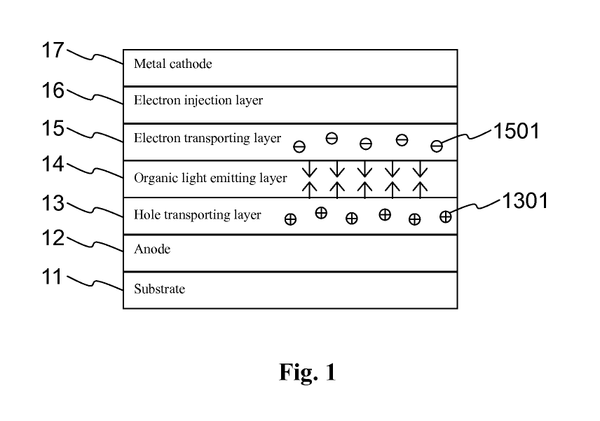

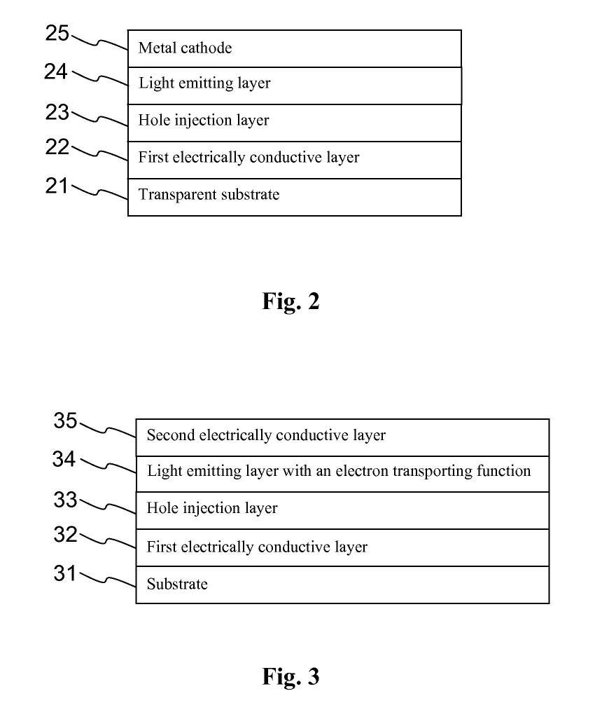

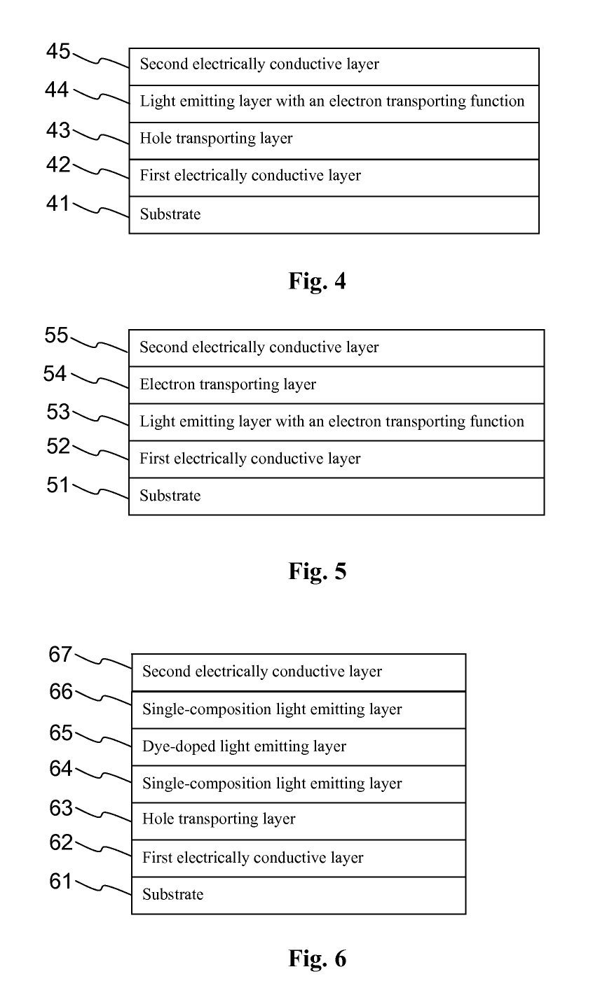

### DETAILED DESCRIPTION OF THE PREFERRED EMBODIMENTS

The aforementioned objectives, characteristics and advantages of the present invention will become apparent with the description of the preferred embodiments of an organic light emitting diode and a method of fabricating the organic light emitting diode of the present invention together with the related drawings. It is noteworthy to point out that same numerals are used for representing the same respective elements respectively in the drawings.

With reference to FIG. 8 for a cross-sectional view of an OLED device in accordance with a preferred embodiment of the present invention, the OLED device comprises a substrate 81, a first electrically conductive layer 82, a hole transporting layer 83, a light emitting layer 84, an electron transporting layer 85, an electron injection layer 86 and a second electrically conductive layer 87 installed sequentially from top to bottom. The first electrically conductive layer 82 is disposed on top of the substrate 81, and the hole transporting layer 83 s disposed on top of the first electrically conductive layer 82, and the light emitting layer 84 s disposed on top of the hole transporting layer 83, and the electron transporting layer 85 s disposed on top of the light emitting layer 84, and the electron injection layer 86 s disposed on top of the electron transporting layer 85, and the second electrically conductive layer 87 s disposed on top of the electron injection layer 86.

The dye-doped light emitting layer 84 includes one or more subject materials and one or more object materials, which can be a fluorescent material or a phosphorescent material, such that the light emitting layer 84 can emit a light, wherein the light emitting layer is composed of one or more subject materials and one or more object materials, and the subject material has a molecular polarity different from the molecular polarity of the object material.

In the meantime, the hole transporting layer 83 is generally made of a hole transporting material, such as poly(3,4-ethylene-dioxythiophene)-poly-(styrenesulfonate) (PEDOT:PSS), and the electron transporting layer 85 is generally made of an electron transporting material such as 1,3,5-tris(N-phenyl-benzimidazol-2-yl) benzene(TPBi), tris(8-hydroxyquinoline)aluminum (Alq3); and the electron injection layer 86 is generally made of an electron injection material such as lithium fluoride (LiF); and the second electrically conductive layer 87 is generally made of an electrically conductive material such as Al; the substrate 81 is generally a glass substrate, a plastic substrate or a metal substrate; and the first electrically conductive layer 82 is generally an indium tin oxide (ITO) layer or an indium zinc oxide (IZO) layer.

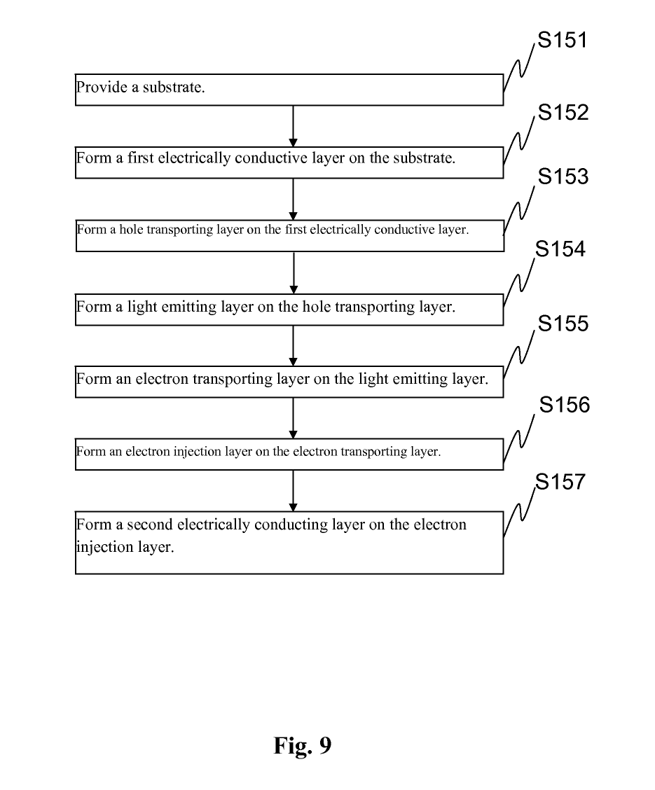

With reference to FIG. 9 for a flow chart of a method of fabricating an OLED device in accordance with a preferred embodiment of the present invention, the method comprises the steps of:

Step (S151): providing a substrate;

Step (S152): forming a first electrically conductive layer on the substrate;

Step (S153): forming a hole transporting layer on the first electrically conductive layer;

Step (S154): forming a light emitting layer containing a subject material and a doped light emitting material on top of the hole transporting layer;

Step (S155): forming an electron transporting layer on top of the light emitting layer;

Step (S156): forming an electron injection layer on top of the electron transporting layer; and

Step (S157): forming a second electrically conductive layer on top of the electron injection layer.

The light emitting layer is composed of one or more subject materials and at least one type of (MDP3FL-doped) object material, and the subject material has a polarity close to the polarity of light emitting material. The hole transporting layer is generally a hole transporting material with PEDOT:PSS; the electron transporting layer is generally made of an electron transporting material such as TPBi and Alq3; the electron injection layer is generally made of an electron injection material such as LiF; the second electrically conductive layer is generally made of an electrically conductive material such as Al; and the substrate is generally a glass substrate, a plastic substrate or a metal substrate.

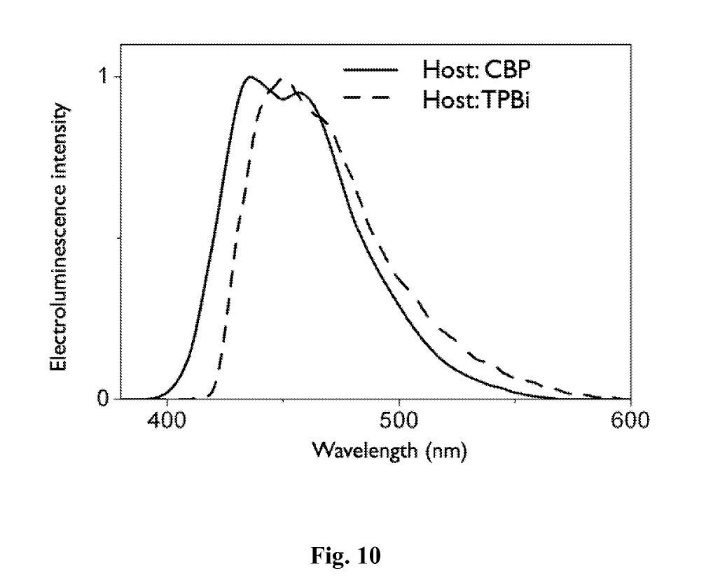

With reference to FIG. 10 for a schematic diagram showing the difference between the present invention and the prior art, an OLED electroluminescence spectroscopy is used for illustrating the comparison.

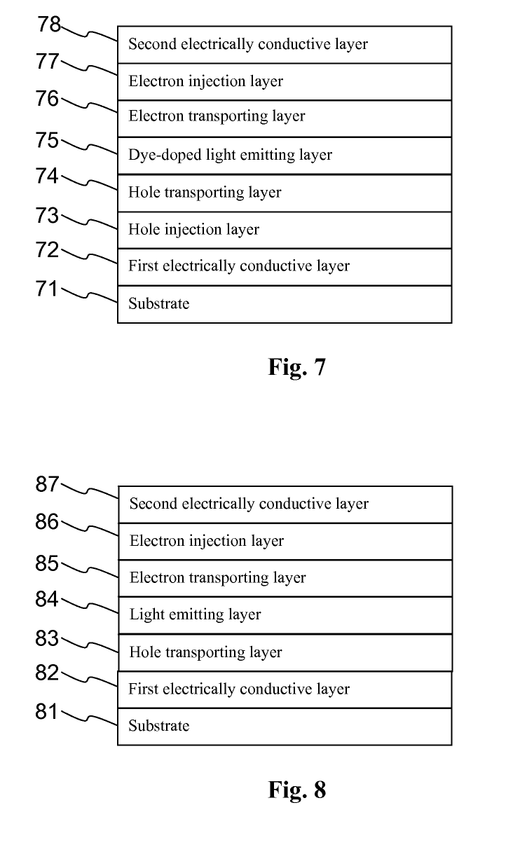

In a first preferred embodiment of the present invention, the OLED device has as structure as shown in FIG. 7, and its manufacturing procedure includes: washing an ITO transparent conductive glass by detergent, deionic water, acetone and isopropyl alcohol sequentially for a supersonic vibration rinse, and then putting the ITO glass into hydrogen peroxide and boiling it for a surface treatment, and drying the surface by nitrogen gas, and spin coating 35 nm PEDOT:PSS transporting layer under the nitrogen environment, and putting the ITO glass into a vacuum chamber at a pressure below 10-5 Torrs, and using an evaporation method to plate a 30 nm light emitting layer 33, 40 nm TPBi electron transporting layer 34, 0.5 nm LiF electron injection layer 35, and 150 nm aluminum electrode 36 on the ITO transparent conductive glass, wherein the light emitting layer 124 is a dye-doped light emitting layer, whose subject material is TPBi, and the couple moment μ of TPBi=3.38 debyes (D), and the dye-doped object material is MDP3FL (with a molecular couple moment=0.44 D), and the doping concentration is 10 wt %, and the difference of the molecular polarities of the subject material and the light emitting material is very large, such that a more red shifting light color is emitted. If the brightness is equal to 100 cd/m², then the electroluminescence (EL) spectroscopy is shown in FIG. 10.

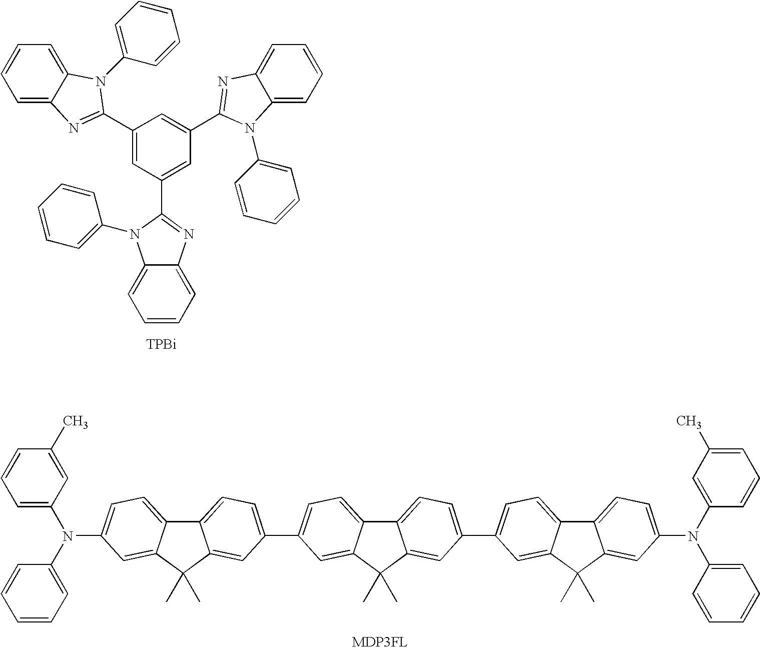

The differences between the method of the present invention and the conventional method of fabricating an OLED device are given. In the light emitting layer of the second preferred embodiment, a subject material CBP 2 having a molecular polarity much different from the polarity of the light emitting material is used, and the structure of the OLED device is the same as the first preferred embodiment. Since the molecular polarity of the subject material CBP is lower (molecular couple moment=0.026 D), and has a very small difference from the molecular polarity of the object material such as MDP3FL, so that the light emitting molecules can be dispersed easily to drive the OLED device to emit a light color with a blue shifting, and its electroluminescence (EL) spectrum is shown in FIG. 10.

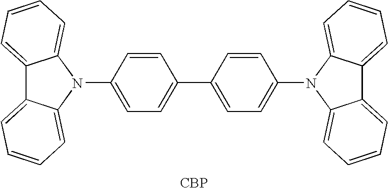

While the invention has been described by means of specific embodiments, numerous modifications and variations could be made thereto by those skilled in the art without departing from the scope and spirit of the invention set forth in the claims.

What is claimed is:

1. An organic light emitting diode (OLED) device, comprising:
a substrate;
a first electrically conductive layer, disposed on the substrate;
a light emitting layer, disposed on top of the first electrically conductive layer; and
a second electrically conductive layer, disposed on top of the light emitting layer;
wherein the light emitting layer is composed of one or more subject materials and at least one MDP3FL-doped object material, and the subject material has a molecular polarity different from the molecular polarity of the object material, and a dipole moment difference greater than 1D.

2. The OLED device of claim 1, wherein the subject material is TPBi.

3. The OLED device of claim 1, wherein the subject material is CBP.

4. The OLED device of claim 1, wherein the light emitting layer is made of a material selected from the collection of a fluorescent material, a phosphorescent material and a combination of fluorescent and phosphorescent materials, such that the light emitting layer can emit a light.

5. The OLED device of claim 1, further comprising at least one functional auxiliary layer formed between the first electrically conductive layer and the light emitting layer.

6. The OLED device of claim 1, further comprising at least one functional auxiliary layer formed between the light emitting layer and the second electrically conductive layer.

7. The OLED device of claim 5, wherein the functional auxiliary layer includes a carrier injection, and the carrier transporting layer is also a carrier blocking layer.

8. The OLED device of claim 6, wherein the functional auxiliary layer includes a carrier injection, and the carrier transporting layer is also a carrier blocking layer.

9. A method of fabricating an organic light emitting diode (OLED) device, comprising:
a substrate;
a first electrically conductive layer, disposed on the substrate;
a light emitting layer, disposed on top of the first electrically conductive layer; and
a second electrically conductive layer, disposed on top of the light emitting layer;
wherein one or more subject materials and at least one MDP3FL-doped object material are mixed into the light emitting layer in advance or during a manufacture, and the subject material has a molecular polarity different from the molecular polarity of the object material, and a dipole moment difference greater than 1D, such that when the light emitting layer is formed, the light emitting material is self-dispersed.

10. The method of fabricating an OLED device as recited in claim 9, wherein the subject material is TPBi.

11. The method of fabricating an OLED device as recited in claim 9, wherein the subject material is CBP.

12. The method of fabricating an OLED device as recited in claim 9, wherein the light emitting layer is made of a material selected from the collection of a fluorescent material, a phosphorescent material, and a combination of fluorescent and phosphorescent materials, such that the light emitting layer can emit a light.

13. The method of fabricating an OLED device as recited in claim 9, further comprising at least one functional auxiliary layer formed between the first electrically conductive layer and the light emitting layer.

14. The method of fabricating an OLED device as recited in claim 9, further comprising at least one functional auxiliary layer formed between the light emitting layer and the second electrically conductive layer.

15. The method of fabricating an OLED device as recited in claim 13, wherein the functional auxiliary layer includes a carrier injection, and the carrier transporting layer is also a carrier blocking layer.

16. The method of fabricating an OLED device as recited in claim 14, wherein the functional auxiliary layer includes a carrier injection, and the carrier transporting layer is also a carrier blocking layer.
